(19) United States
(12) Patent Application Publication
(10) Pub. No.: US 2021/0208193 A1
(43) Pub. Date: Jul. 8, 2021

(54) Wafer Fixture For Testing And Transport

(71) Applicant: II-VI Delaware, Inc., Wilmington, DE (US)

(72) Inventors: Raven Persaud, Old Bridge, NJ (US); Liam Larkin, Quakertown, PA (US); Thomas Barrie, Anandale, NJ (US); Garrett Korpinen, Bethlehem, PA (US); John W. Stayt, Jr., Schnecksville, PA (US); Rajat Jain, Easton, PA (US); Christopher T. Martin, Maplewood, NJ (US); George E. Harris, Garland, TX (US)

(73) Assignee: II-VI Delaware, Inc., Wilmington, DE (US)

(21) Appl. No.: 17/056,608

(22) PCT Filed: May 16, 2019
(86) PCT No.: PCT/US19/32608

§ 371 Date: Nov. 18, 2020

Related U.S. Application Data
(60) Provisional application No. 62/675,048, filed on May 22, 2018.

(51) Int. Cl. G01R 31/28; G01R 1/04; H01L 21/673; H01L 21/683

(52) U.S. Cl. CPC G01R 31/2831; H01L 21/6838; H01L 21/67346; G01R 1/0491

(57) ABSTRACT

A wafer handling fixture is used to transport a finished semiconductor wafer from one post-fabrication procedure to another (e.g., testing, inspection, cleaning, dicing, or shipping) in a manner that maintains the wafer in its “flattened” form and eliminates the possibility for a wafer to later spring back into a bowed form. The wafer handling fixture includes a surface stiction film to which the wafer will naturally adhere, and uses a wafer release mechanism included in a bottom support plate to permit for the “controlled” transfer of the wafer from the handling fixture to testing/inspection equipment.

### CROSS-REFERENCE TO RELATED APPLICATIONS

This application claims the benefit of U.S. Provisional Application No. 62/675,048, filed May 22, 2018 and herein incorporated by reference.

### TECHNICAL FIELD

The present invention relates to the production of semiconductor wafers and, more particularly, to a handling fixture for transporting thinned wafers in a manner that eliminates opportunities for post-fabrication bow to re-occur in the thinned wafer structure.

### BACKGROUND OF THE INVENTION

In the manufacturing of semiconductor devices, a wafer is subjected to a series of complex processes. These processes include, for example, the formation of structures on the wafer, e.g., deposition and patterning of films to form wiring, transistors, vias, metal pads, solder bumps, chip to chip interconnects, etc. Today's wafers are typically thinned at the completion of the actual device fabrication process, allowing for the backside of the wafer to be used as an electrical contact pad for the final structure. Prior to thinning, a semiconductor wafer has its own structural integrity and tends to exhibit a bow within the range of +/−300 μm, which can be handled by most tools. However, the act of thinning of the wafer eliminates this structural integrity such that the wafer is able to bow and thus creates a situation where this bow interferes with post-fabrication operations. Indeed, wafers that have been thinned to exhibit a thickness on the order of 100 μm (or even less) are extremely fragile, exhibit significant bow/warpage, and must be supported over their full dimensions to prevent cracking and breaking.

Post-fabrication processes related to inspecting and testing a wafer, particularly a “finished” wafer, require a significant amount of wafer handling, either by personnel or via automated handling equipment. As a result, a bowed wafer needs to be flattened before performing any kind of testing or inspection. For example, most operations require the use of a vacuum chuck and include operations such as loading a wafer on a vacuum chuck, followed by removing the wafer from the chuck at the completion of testing/inspection. Once removed from the vacuum chuck, a given wafer may “spring” back into its natural, bowed condition and will then need to be re-flattened before performing the next inspection, testing or transport operation.

In most conventional systems, a “bare” wafer (i.e., an un-supported wafer) is directly handled during these post-fabrication procedures. The bare wafer may be handled by the personnel performing the process or handled by a mechanized robotic system. In any case, the bare wafer needs to be gently re-flattened before performing any type of testing, inspection, or the like.

Obviously, the repeated flattening and flexing of a wafer increases the probability of wafers cleaving and breaking. Inasmuch as a wafer at this point in the process is essentially the finished product, any cleaving or breakage incurs a significant financial loss, and may also interrupt the fabrication process itself by requiring additional wafers to be added to a production lot.

### SUMMARY OF THE INVENTION

The present invention addresses these concerns and takes the form of a wafer fixture that maintains wafer flatness during the handling steps involved in post-fabrication activities such as cleaning, inspection, testing and transport.

In accordance with the principles of the present invention, an exemplary wafer handling fixture is provided that remains paired with a thinned wafer and supports the wafer as it is handled during subsequent finishing procedures. The handling fixture is pressure-controlled to release the thinned wafer only when positioned on, and held in place by, another piece of equipment used to perform a post-fabrication procedure (e.g., within a vacuum chuck for post-fabrication testing).

Exemplary embodiments of the wafer handling fixture of the present invention take of the form of a three-layer structure including a relatively rigid bottom support plate that is covered by a combination of a thin mesh layer and a surface “stiction” layer (i.e., a layer of somewhat tacky material). A semiconductor wafer will naturally adhere to the stiction layer by a static friction force (i.e., “stiction”) that does not affect the operational properties of the devices fabricated on the wafer. One or more apertures are formed within the bottom support plate, where the application of a change in pressure through the aperture(s) is used to overcome the static friction force and allow the wafer to be released from the handling fixture when desired (e.g., when loaded into a testing fixture). The force may be a positive pressure, or an applied vacuum force. In one embodiment, a Venturi vacuum generator may be created within the bottom support plate itself and used to control the release of the wafer.

Thus, a wafer that is releasably attached to the inventive wafer handling fixture may be transported by personnel and only released from the fixture when in place on equipment used to perform a post-fabrication procedure (clean, test, dice, etc.). Upon completion of the procedure, the handling fixture is again disposed over the wafer, which will naturally re-adhere to the surface stiction layer of the wafer handling fixture, allowing the “fixtured” wafer to be removed from the equipment and transported to another location.

The stiction layer may be configured to exhibit various patterns of surface tackiness (e.g., radial increase in tackiness from center, outer periphery of increased tackiness, and the like) to accommodate different attributes of the wafer (e.g., diameter, thickness, etc.). The mesh layer may have different patterns of openings in a fabric, for example, that are selected to adjust the amount of force required to overcome the stiction attachment for a given wafer design. Alternatively, the mesh layer may take the form of appropriate grid pattern (and/or shapes) formed directly in the surface of the support substrate itself. The variations in stiction, mesh structure, and aperture pattern are all considered to be design considerations that may be adjusted, as need be, depending on specific factors of a given application. For example, the overall diameter of the wafer may determine the number (and pattern) of apertures to be used, where a larger wafer (e.g., a 10-inch diameter wafer) may be more easily released by employing several apertures disposed at disparate locations. With an extremely thin wafer (e.g., thickness less than about 50 μm), it may be preferred to use a more “closed” mesh pattern that controls the release action.

A wafer handling fixture may be further configured to include a module for performing various environmental tests (temperature, humidity, barometric pressure, etc.) during the post-fabrication production flow of an attached wafer, with the ability to either store the environmental data on the handling fixture itself or transmit the information to a remote monitoring facility. Additionally, the wafer handling fixture may be configured to also include a component for storing a unique ID of the attached wafer, as well as detailed information regarding its specific fabrication process steps, useful for inventory tracking and quality assurance procedures.

An exemplary wafer handling fixture formed in accordance with the present invention may also be used as a packaging element in the shipping of a wafer to a customer or other facility. Alternatively, an exemplary wafer handling fixture may be re-used with multiple wafers, one after the other, subsequent to the final post-fabrication operation (typically, dicing the wafer into individual die or components). A pair of inventive wafer handling fixtures may be used to “flip” a wafer (to present the opposite surface for testing, inspection, etc.) without the need for other equipment or removing the wafer from a fixture.

Advantageously, the use of the inventive handling fixture allows for associated automated equipment (robotic means) to be used to move the fixture itself from one location to another.

An exemplary embodiment of the present invention takes the form of a fixture for maintaining flatness of a semiconductor wafer during handling, where the fixture comprises a bottom support plate including a wafer release mechanism, a mesh structure disposed to cover a major surface area of the bottom support plate, and a surface film of a polymer material disposed on the mesh structure. The surface film creates a stiction force between the fixture and a semiconductor wafer placed on the surface film such that the semiconductor wafer remains affixed to the fixture during handling to eliminate opportunities for wafer bow to be re-introduced during handling, the stiction force only overcome by activation of the wafer release mechanism.

Another exemplary embodiment of the present invention may be defined as a method of handling a processed semiconductor wafer to prevent wafer bowing, the method including

disposing the processed semiconductor wafer on a wafer handling fixture (the wafer handling fixture comprising the elements described above), moving the wafer handling fixture with the disposed wafer to an operation station associated with a manufacturing process, loading the wafer handling fixture onto the operation station such that an exposed surface of the processed semiconductor wafer contacts a support mechanism within the operation state, applying a local vacuum force to hold the exposed surface of the processed semiconductor wafer against the support mechanism of the operation station, and activating the release mechanism of the wafer handling fixture to overcome the stiction force between the wafer and the handling fixture, allowing an opposing wafer surface to be visible and allowing the wafer handling fixture to be removed from the vicinity of the operation station.

Other and further aspects and embodiments of the present invention will become apparent during the course of the following discussion and by reference to the accompanying drawings.

### BRIEF DESCRIPTION OF THE DRAWINGS

Referring now to the drawings, where like numerals represent like parts in several views:

FIG. 1 is a cross-sectional view of an exemplary thinned semiconductor wafer, illustrating the possible tensile and compressive forces that cause the wafer to bow;

FIG. 2 is a top view of an exemplary wafer handling fixture formed in accordance with the principles of the present invention;

FIG. 3 is a side view of the wafer handling fixture of FIG. 2;

FIG. 4 is a photograph of a thinned semiconductor wafer in place on a wafer handling fixture formed in accordance with the principles of the present invention;

FIG. 5 is a side view similar to FIG. 3, in this case with a semiconductor wafer adhered to the surface stiction film of the wafer handling fixture;

FIG. 6 is an underside view of an exemplary bottom support plate component of the inventive wafer handling fixture, where the illustrated bottom support plate is formed to include a plurality of separate ports for providing a change in pressure to release a wafer from the fixture;

FIG. 7 illustrates an exemplary bottom support plate of the wafer handling fixture that is particularly configured to include a Venturi vacuum generator as the wafer release mechanism;

FIG. 8 depicts a first step in a process of transporting a fixture-supported wafer to a vacuum chuck and positioning the fixture over the vacuum chuck;

FIG. 9 depicts a following step, including activation of the wafer release mechanism to removes the fixture from the wafer, the wafer remaining held in place by the vacuum pulled through the vacuum chuck;

FIG. 10 illustrates an exemplary configuration of the surface stiction layer of the wafer handling fixture;

FIG. 11 illustrates different patterns that may be used in the formation of the mesh structure of the wafer handling fixture;

FIG. 12 illustrates an exemplary “enhanced” wafer handling fixture formed to include components and modules for inventory and tracking purposes, with the possibility of also recording environmental conditions experienced by the post-fabrication wafer as supported on the wafer handling fixture;

FIG. 13 is a flowchart illustrating a series of steps that may be performed by the enhanced wafer handling fixture of FIG. 12; and

FIG. 14 contains a set of drawings depicting a process that may be used to “flip” over a wafer, using a pair of wafer handling fixtures formed in accordance with the present invention.

### DETAILED DESCRIPTION

It has been found through standard semiconductor manufacturing processes that thinned wafers can exceed process tool wafer handler capabilities and bow limits. This, in turn, can result in wafer mis-handling, tool errors, and excessive wafer breakage during wafer finishing process steps. By way of example, it has been found that thinning of the wafer results in fluctuations in wafer bow.

Ideally, a finished, thinned wafer would be perfectly flat, but process films added to the wafer tend to produce finished wafers that are significantly bowed. The actual final shape of the wafer is mostly determined by the balance of film stresses (from both front and back side films). Wafer distortion is a problem because highly bowed/warped wafers are difficult, if not impossible, to handle once they are freed from their film frames.

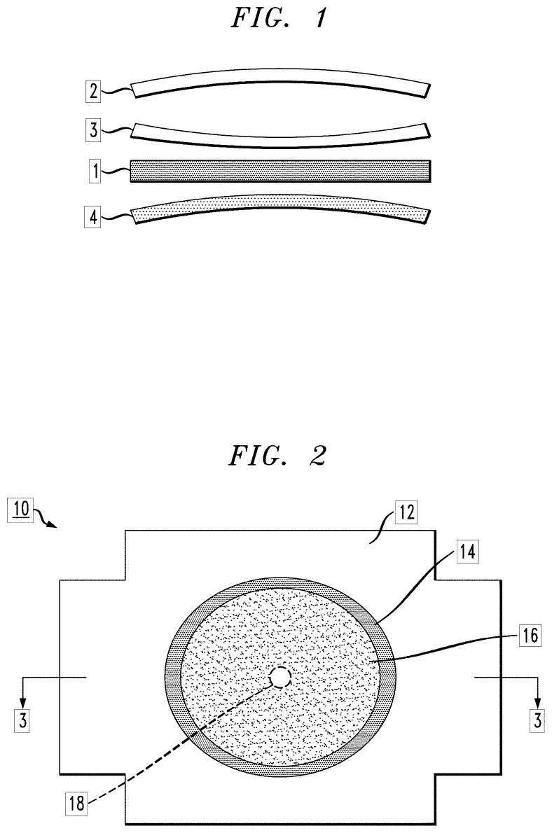

FIG. 1 is a cross-section view of an exemplary wafer 1. According to devices and methods herein, wafer 1 may comprise a semiconductor material, such as silicon, a III-V compound (e.g., GaAs or InP) or other compositions as known in the art. As mentioned above, wafer 1 is subjected to a variety of stresses and strains during the manufacturing process, as represented by the curves in the figure. For example, the top curve 2 may represent tensile strained circuit side metal films; the next curve 3 may represent compressively strained circuit side dielectric films. Bottom curve 4 may represent the final, cumulative bow remaining in a post-fabrication wafer that has been thinned to a value of about 100 μm (perhaps even less). It is to be understood that wafer 1 may be subjected to many other stresses and/or strains, which, in combination, result a bowed or other irregular shape of the post-production thinned wafer.

The present invention addresses these concerns and takes the form of a wafer handling fixture that is used to transport a wafer from one post-fabrication procedure to another (e.g., testing, inspection, cleaning, dicing, or shipping) in a manner that maintains the wafer in its “flattened” form and eliminates the possibility for a wafer to later spring back into a bowed form.

An exemplary wafer handling fixture 10 formed in accordance with the present invention is shown in a top view in FIG. 2, with a cut-away side view in FIG. 3 (it is to be understood that FIG. 3 is not drawn to scale). Wafer handling fixture 10 comprises a bottom support plate 12 of a suitable material that is relatively stiff, lightweight and easy to handle (for example, a high impact strength plastic such as a polycarbonate resin thermoplastic). Specific suitable materials for bottom support 12 include the following: Lexan® thermoplastic developed by General Electric Company or a polymethyl methacrylate, such as Plexiglas® material developed by Rohm & Haas Company.

In exemplary embodiments, bottom support plate 12 may range in thickness anywhere from about 1 mm to 2 cm, depending on the particular application and convenience of the user. In general, the thickness of bottom support plate 12 does not impact the performance of wafer handling fixture 10 and may be thought of more as a design parameter associated with ease of use, expense, particular application and the like. For example, if a given fixture is to be re-used from one wafer to another, it may be preferred to be relatively thick. Alternatively, if a given fixture is intended to support a wafer during shipping, a thinner support plate reduces shipping weight and volume.

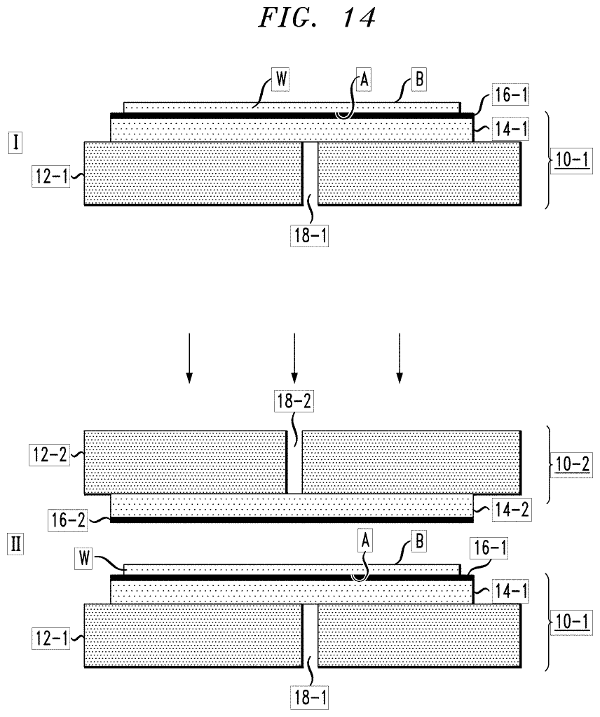

Wafer handling fixture 10 is shown as further comprising a thin mesh structure 14 that is disposed on support plate 12, with a surface layer 16 of a somewhat tacky material disposed over mesh structure 14. The arrangement of these layers is best shown in the cut-away side view of FIG. 3 (again, not to scale with respect to the relative thicknesses here or in following drawings). Mesh structure 14 may comprise a specific type of woven material, with the openings in the material controlled for different applications. Alternatively, mesh structure 14 may comprise an exemplary grid pattern formed as shallow channels in the top surface of bottom support plate 12 (it is to be noted that instead of a specific grid pattern, an embossed pattern of particular shapes (see, for example, FIG. 11) may be directly formed in the top surface of bottom support plate 12.

Surface layer 16 itself may comprise a material such as, but not limited to, acrylics, plastics, silicone resins, cellulose acetate sheets, polyethylene, and polymer materials of the like. In most cases, surface layer 16 will exhibit a thickness somewhere in the range of about 10 μm to 5 mm. In a preferred embodiment, both mesh structure 14 and surface layer 16 are circular in form, overlapping as shown.

FIG. 4 is a photograph of a wafer as in position on an exemplary wafer handling fixture 10 formed in accordance with the present invention. In accordance with the present invention, a wafer will sufficiently adhere to surface layer 16 of handling fixture 10 such that any bow present in the wafer is eliminated upon placement of the wafer on surface layer 16. Indeed, a type of “static friction” (“stiction”) force is created between surface layer 16 and the surface of the wafer, allowing for fabrication personnel (or automatic handling equipment) to manipulate wafer handling fixture 10 without dislodging the wafer from its adherence to surface layer 16.

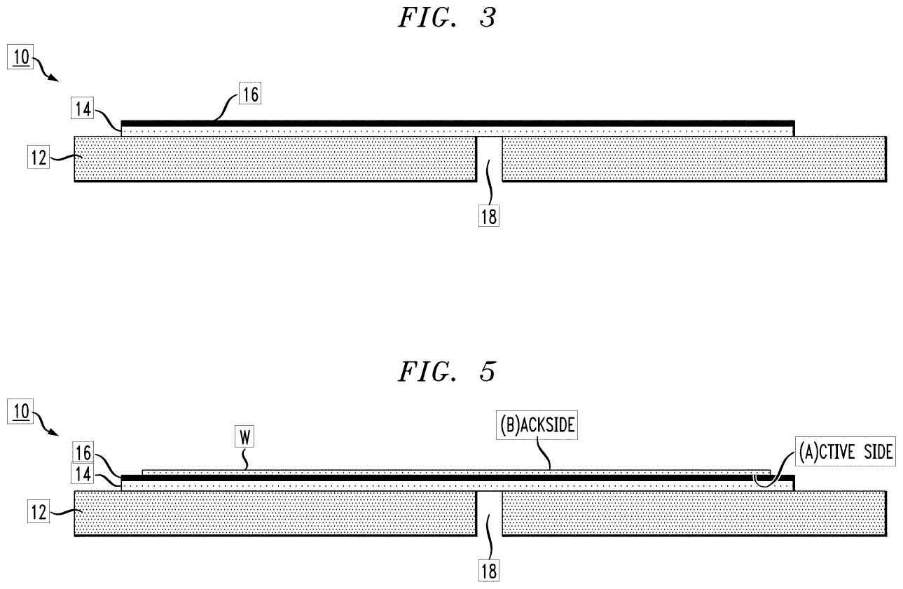

FIG. 5 is a view showing an exemplary wafer W in place on fixture 10. Depending on the next processing step to be performed, wafer W is either positioned with its active surface A exposed (and thus backside B adhered to wafer handling fixture 10), or vice versa. For the purposes of this discussion, wafer W is shown in FIG. 5 as mounted such that active surface A is adhered to surface layer 16, with backside B exposed. After this initial placement of a wafer on handing fixture 10, the wafer will not again be left “unsupported” in a situation where wafer bow could be re-introduced. Said another way, the elimination of “bare wafer” handling is a significant advantage of the wafer handling fixture of the present invention and the method in which it is used as part of the manufacturing process.

A feature of wafer handling fixture 10 is the ease with which a given wafer may be controllably released from the fixture when the need arises. In many cases, for example, a fabricated wafer needs to loaded into a vacuum chuck so that its active surface is exposed and available for testing, cleaning, and the like. Thus, while an aspect of the invention is the assurance that the wafer will maintain its adherence to wafer handling fixture 10 during handling and transport, it is equally important that the wafer is easily detached from the fixture when desired (such as after loading in a vacuum chuck) without incurring any damage to the wafer.

Therefore, wafer handling fixture 10 is further configured in accordance with the present invention to include a pressure-controlled release mechanism for detaching the wafer from handling fixture 10 under the control of the user. That is, the release is controlled such that handling fixture 10 is only removed after the wafer is itself fully supported by another device (such as a vacuum chuck, for example) so that there is no opportunity for the wafer to spring back into a bowed form.

In one exemplary embodiment, the release mechanism takes the form of a release port formed through the thickness of bottom support plate 12. Reference is made to FIGS. 2 and 3, which show a release port (aperture) 18 formed completely through the thickness bottom support plate 12 of fixture 10. In the particular embodiment of these illustrations, a single release port is illustrated and located in essentially the center of support plate 12. Release may use either a positive pressure or vacuum to separate wafer W from surface layer 16.

Thus, once “fixtured” wafer W is positioned on a piece of equipment and held in place via the equipment's vacuum force, wafer W is then released from handling fixture 10. In one exemplary embodiment, a vacuum force may be applied through port 18 of handling fixture 10 to break the stiction force between wafer W and surface layer 16, releasing wafer W from handling fixture 10. Alternatively, a positive pressure air flow may be applied through port 18. In either case, the change in pressure is sufficient to break the stiction force between surface layer 16 and wafer W, releasing wafer W from wafer handling fixture 10. The release of wafer W from surface layer 16 relies on the reduction of surface tension between surface layer 16 and wafer W. For example, the presence of an applied vacuum functions to pull surface layer 16 into the spacings within the fabric (or plate-integrated pattern) of mesh structure 14, reducing the physical contact between surface layer 16 and wafer W.

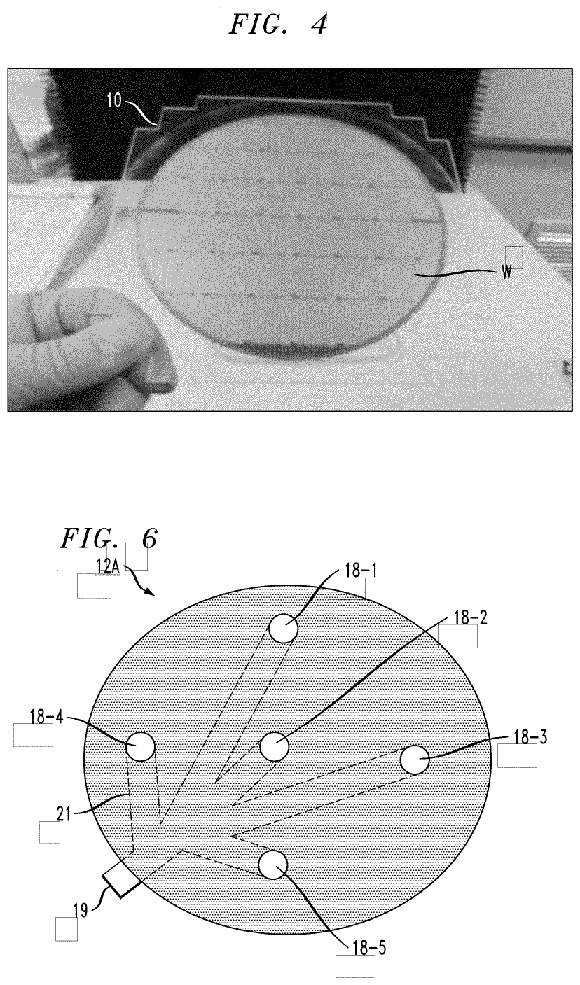

It is to be understood that other configurations of this embodiment of the present invention may use multiple ports, disposed at various, spaced-apart locations across support plate 12. FIG. 6 is a bottom view of an exemplary support plate 12A that utilizes a set of five separate apertures 18-1, 18-2, 18-3, 18-4 and 18-5. It is contemplated that large-diameter wafers (for example, over 10 inches in diameter) may be more easily released when multiple sectors of surface stiction layer 16 are subjected to a change in pressure. Additionally, it is to be understood that a single vacuum port, shown as port 19 in FIG. 6, may be in fluid communication with the set of apertures 18 to apply the change in force, as indicated by dotted line channels 21 formed within support plate 12A, rather than require individual vacuum sources to be paired with multiple apertures in a one-to-one manner.

Other embodiments of the present invention may use other arrangements for releasing the wafer from the handling fixture. In particular, on-fixture arrangements may be used to supply the release force, thus eliminating the need for a separate vacuum source, for example.

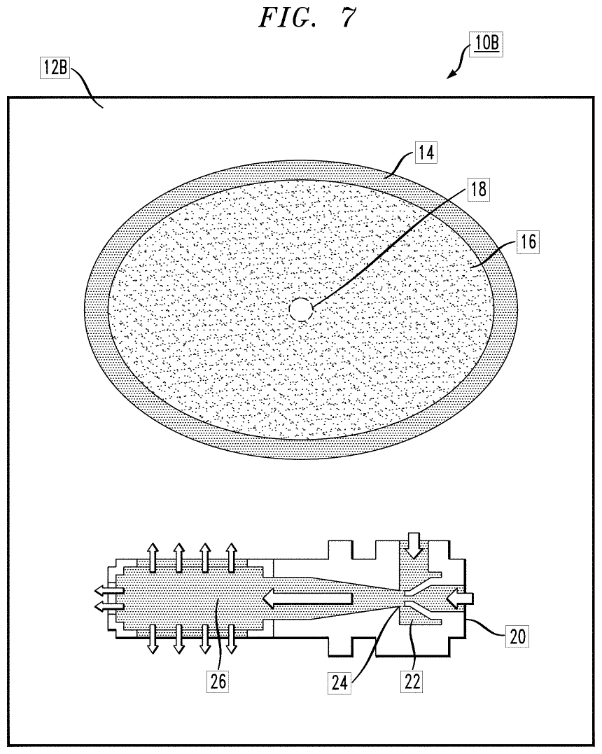

FIG. 7 illustrates one such alternative embodiment of the present invention, denoted as wafer fixture 10B, that further includes a Venturi vacuum generator 20 patterned directly into the material of a bottom support plate 12B. A Venturi vacuum generator is formed by the passage of a compressed air stream through a specific physical structure that creates a vacuum force by changes in flow pressure through regions of different spatial geometries within the physical structure. Here, compressed air is introduced into an intake chamber 22 of Venturi vacuum generator 20. The compressed air is then forced through a small portal 24 and thereafter enters a large chamber 26. This flow results in creating a vacuum that pulls through channels and apertures (such as channels 21 and apertures 18, described above) to provide the desired force to release wafer W from surface layer 16.

As mentioned above, it is an advantage of the apparatus and method of the present invention that once a wafer is initially mounted on handling fixture 10, it will no longer be placed in any situation where it will have the opportunity to “flex” and present a bowed form. Once a finished wafer is ready for these last manufacturing steps of inspection, cleaning and testing, it is attached to handling fixture 10 and is thereafter only handled via its attachment to fixture 10. Any bow present in the wafer immediately after fabrication is eliminated (perhaps using prior art elimination techniques of gently pushing on the wafer) during the first time it is attached to fixture 10. Thereafter, wafer handling fixture 10 is only removed once the wafer is loaded into equipment having a vacuum source of its own that maintains the wafer in flat form.

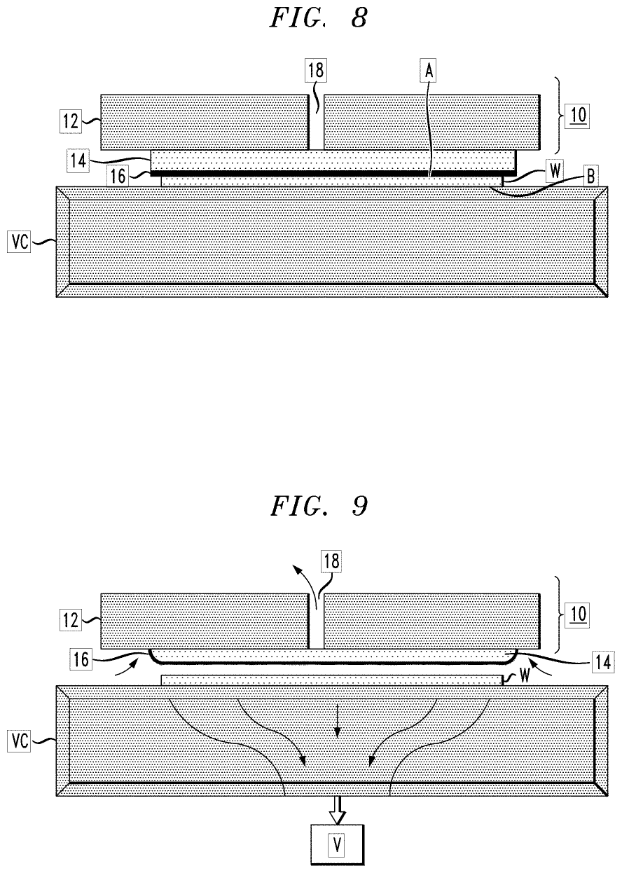

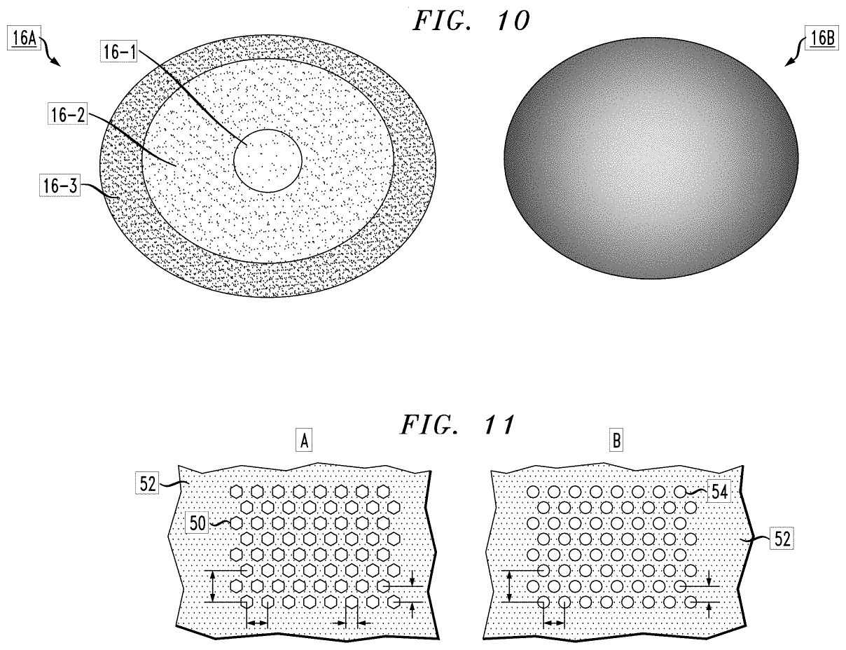

FIGS. 8 and 9 illustrate an exemplary process of transferring a thinned wafer from handling fixture 10 to a given workpiece, here shown as a vacuum chuck VC. In the view of FIG. 8, wafer handling fixture 10 (with wafer W still attached) is shown as loaded onto a conventional vacuum chuck (VC), as used for wafer-level testing and cleaning. Wafer handling fixture 10 is positioned upside-down over vacuum chuck VC so that the exposed surface of the wafer (for example, the backside B as shown in the illustration of FIG. 5) is positioned over the fixture opening.

Once handling fixture 10 has been positioned on vacuum chuck VC, a workpiece vacuum source V is activated to secure backside B of wafer W (i.e., the “exposed” wafer surface as wafer W is disposed on handling fixture 10) to vacuum chuck VC. At this point in the process, handling fixture 10 is still secured to the opposing wafer surface. Thus, wafer W is “fixed” in place between vacuum chuck VC and handling fixture 10, held in place by both components.

In the following step, a controlled pressure is applied to bottom support plate 12 of wafer handling fixture 10 to release wafer W from surface layer 16. FIG. 9 uses an arrow to illustrate the application of a vacuum force through aperture 18 of wafer handling fixture 10. As shown, and by comparison with FIG. 8, the application of a vacuum draws surface layer 16 toward (and even into the openings within) mesh structure 14, releasing wafer W from handling fixture 10. Fixture 10 is then easily lifted away from wafer W, which is now held securely in place by workpiece vacuum V associated with vacuum chuck VC. Preferably, wafer holding fixture 10 is stored in a manner such that surface layer 16 retains its pristine qualities until it is re-attached to wafer W.

With the release of wafer W from handling fixture 10, and the removal of handling fixture 10 to a storage location, surface A of wafer W is uncovered (exposed) and available for the specific post-fabrication process (surface B of wafer W being held down against vacuum chuck VC).

Once the procedure being performed on wafer W is completed and it is necessary to transport wafer W to another location, fixture 10 is re-positioned over wafer W and workpiece vacuum V is turned off. With holding fixture 10 back in place, the exposed surface of wafer W (here, active surface A) will once again naturally adhere to surface stiction layer 16 of handling fixture 10, allowing for the supported wafer to be removed from vacuum chuck VC without the possibility of re-introducing wafer bow (which would otherwise occur if the wafer were manually/automatically removed in bare form from the apparatus). Therefore, in accordance with the principles of the present invention, wafers may be moved from location to location without need to be handled in “bare” wafer form; the wafer remains paired with a handling fixture at all points in time. Moreover, the use of handling fixture 10 to provide wafer transport allows for other automated processes to be used to provide the actual movement of the “fixtured” wafer from one location to another.

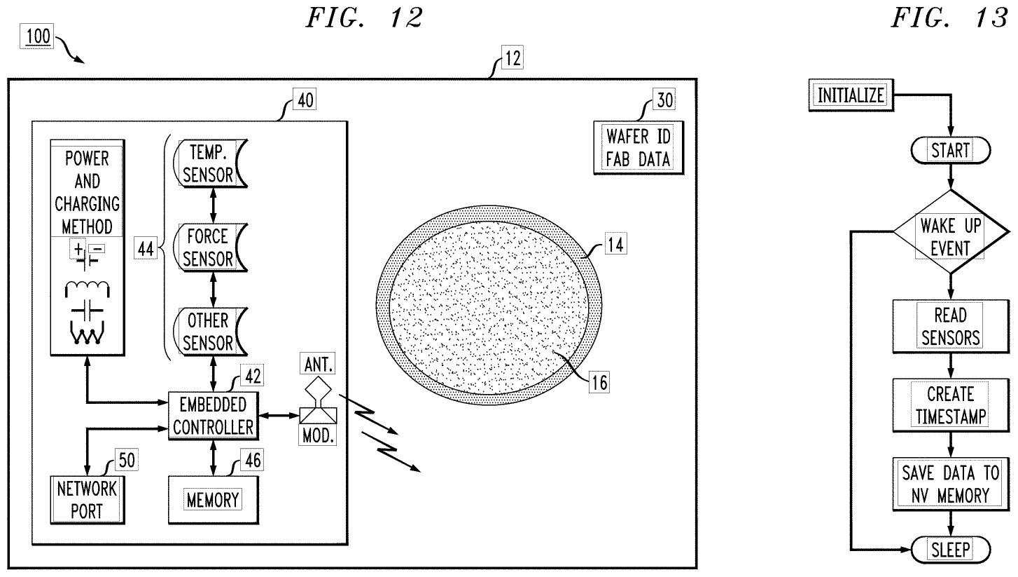

It is to be understood that besides using any one of the variety of materials mentioned above for surface stiction layer 16, various other materials may also be used. Indeed, as mentioned above, surface stiction layer 16 may be particularly configured to provide any desired degree of “tackiness” for a given situation. For example, with some wafers, it may desirable to create a radial change in tackiness across the extent of surface layer 16, as measured from the center. In particular, an exemplary configuration may exhibit an increase in tackiness in the radial direction outward from the center C of surface layer 16. This configuration is shown as surface stiction layer 16A in FIG. 10. Here, an inner circle 16-1 exhibits the least amount of tackiness, with a first ring 16-2 being somewhat tackier, and a second (outer ring) 16-3 having the greatest degree of tackiness. Instead of utilizing a structure with distinct rings, the increase may be gradual, as shown in the surface stiction layer 16B of FIG. 10.

In combination with these variations in the properties of surface stiction layer 16, mesh structure 14 may be modified in terms of its mesh pattern, the geometry of included spaces, the spacing between adjacent spaces, and the like, are all factors that may be taken into consideration in the formation of wafer handling fixture 10 for a given application. FIG. 11 illustrates two different exemplary mesh patterns that may be utilized in the formation of mesh structure 14. Pattern A includes a plurality of hexagonal openings 50 in a piece of thin material 52, where the openings are spaced apart by the dimensions as shown (the spacing is a design feature subject to change). Pattern B includes a plurality of circular openings 54 formed in material 52; again, the spacing between adjacent circular openings 54 a design consideration. As mentioned above, these patterns (or any other suitable pattern or grid structure) may be directly formed (e.g., embossed, machined, etched, etc.) within the top surface of bottom support plate 12.

Besides the inclusion of a vacuum generator, it is contemplated that an exemplary wafer handling fixture formed in accordance with the present invention may be enhanced to include various modules for storing information related to the specific wafer. For example, a fabrication history module may store a unique ID number of the specific wafer and the detailed processing steps used in its fabrication. An environment module may include one or more sensors (e.g., temperature, humidity, pressure, applied force, shock, etc.) to create an “environment” history for a particular wafer, which may thereafter accompany a wafer when leaving a manufacturing location. Obviously, these various processing history and environmental information functions may be supplied by a single module, or a set of modules.

FIG. 12 illustrates an exemplary fabrication history module 30 and an on-fixture monitoring module 40 that may be included within an exemplary enhanced wafer handling fixture 100 for implementing the various functions described above. Personnel associated with the fabrication process may be tasked with entering a unique ID into history module 30, and thereafter supplement the information with specific details regarding the fabrication process (e.g., a timestamp for each process, identification of a specific machine used for each process, process parameters, and the like). In many of today's inventory control and quality assurance programs, having this information directly paired with the wafer is extremely beneficial.

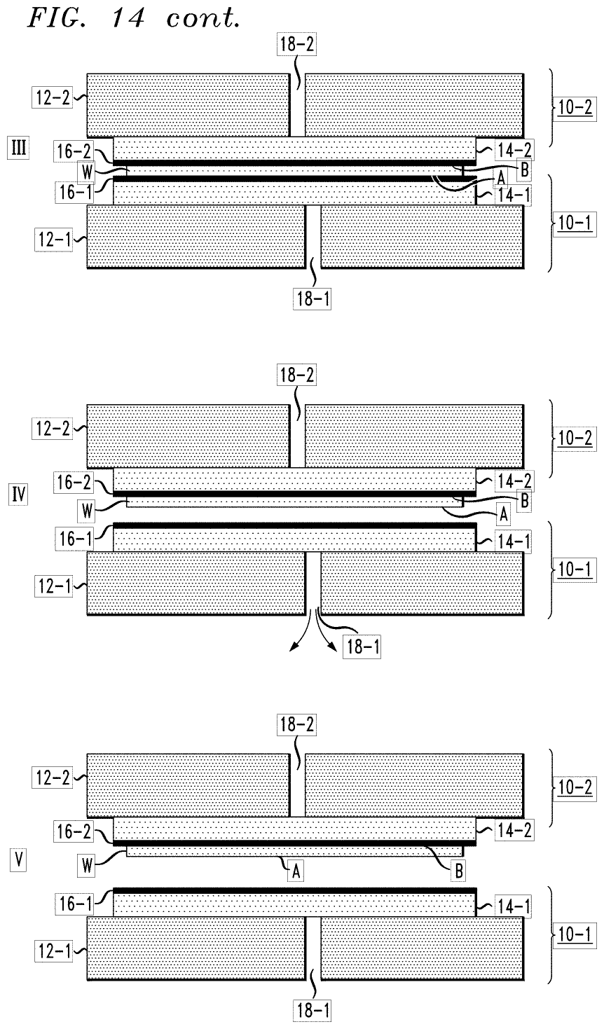

Monitoring system 40 is shown as including an embedded controller 42 comprising a programmable logic device for implementing instructions to perform sensor measurements and store the measurements. FIG. 13 is a flowchart of one exemplary process sequence that may be implemented by controller 42. Also shown in monitoring system 40 is a plurality of individual sensors 44 (e.g., temperature, force, and the like), each being activated by embedded controller 42. A memory module 46 may be included on-board within monitoring system 40 for storing these measurements.

Also shown in FIG. 12 is an included network port 50 that may be used to provide a wireless connection between modules 30, 40 and a larger manufacturing testing/inspection system. For example, changes to be made in the monitoring system may be input to embedded controller 42 via network port 50. An on-board power module 52 is also shown in FIG. 12.

It is further contemplated that a pair of wafer handling fixtures formed in accordance with the present invention may be used to essentially “flip over” a semiconductor wafer to expose the opposing surface without needing to demount the wafer from the fixture. For example, if a wafer is attached to a first fixture 10-1 such that the bottom side B of the wafer is exposed, a second fixture 10-2 may be positioned over fixture 10-1 such that this bottom side B adheres to surface layer 16-2 of second fixture 10-2. The application of a vacuum (for example) through port 18-1 of first fixture 10-1 releases the wafer from first fixture 10-1 so that it will only be contacting second fixture 10-2. This transfer thus results in active side A of the wafer now being exposed.

An exemplary set of flipping process steps is illustrated in a set of diagrams shown in FIG. 14. Diagram I shows wafer W attached to first fixture 10-1 in an orientation where active surface A is adhered to surface stiction layer 16-1, with backside surface B exposed. Diagram II shows second fixture 10-2 being positioned over first fixture 10-1 such that surface stiction layer 16-2 of second fixture 10-2 is disposed over backside B of wafer W. In diagram III, second fixture 10-2 has been brought into contact with first fixture 10-1, with backside B of wafer W now in contact with surface stiction layer 16-2. Essentially, wafer W is now sandwiched between first fixture 10-1 and second fixture 10-2.

At this point in the process, as shown in diagram IV, a vacuum (or positive pressure) is applied via aperture 18-1 to release wafer W from fixture 10-1 (that is, to break the stiction force holding active side A of wafer W to surface stiction layer 16-1). With the attachment of backside B of wafer W already secured to surface stiction layer 16-2 of fixture 10-2, the release of wafer W from first fixture 10-1 completes the transfer of wafer W to second fixture 10-2, as shown in diagram V.

It is further contemplated that out of an abundance of caution a wafer may be retained between a pair of inventive fixtures (e.g., fixtures 10-1 and 10-2) during shipping or other transport steps that would otherwise expose the wafer to undesirable contaminants. Thus, the configuration as shown in diagram III of FIG. 14 may be used to ensure that both surfaces of the finished wafer will be protected during transport.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments.

The terminology used herein was chosen to best explain the principles of the embodiments, the practical application or technical improvement over technologies found in the marketplace, or to enable others of ordinary skill in the art to understand the embodiments disclosed herein.

1. A fixture for maintaining flatness of a semiconductor wafer during handling, the fixture comprising:
a bottom support plate including a wafer release mechanism;
a mesh structure disposed to cover a major surface area of the bottom support plate; and
a surface film of a polymer material disposed on the mesh structure, the surface film creating a stiction force between the fixture and a semiconductor wafer placed on the surface film such that the semiconductor wafer remains affixed to the fixture during handling, and released by activation of the wafer release mechanism.

2. The fixture as defined in claim 1 wherein the wafer release mechanism of the bottom support plate comprises at least one port for introducing a change in pressure at the surface film, the change in pressure sufficient to overcome the stiction force.

3. The fixture as defined in claim 2 wherein a positive change in pressure is introduced through the at least one port.

4. The fixture as defined in claim 2 wherein a negative change in pressure is introduced through the at least one port.

5. The fixture as defined in claim 2 wherein the at least one port comprises a single port configured as an aperture disposed through the thickness of the bottom support plate.

6. The fixture as defined in claim 2 wherein the at least one port comprises a plurality of ports disposed across a surface of the bottom support plate.

7. The fixture as defined in claim 6 wherein the bottom support plate further comprises a single inlet port in fluid communication with the plurality of ports so as to introduce a change in pressure at various locations across the surface of the bottom support plate.

8. The fixture as defined in claim 1 wherein the bottom support plate is formed of a plastic material.

9. The fixture as defined in claim 8 wherein the bottom support plate is formed of a plastic material selected from the group consisting of: high impact strength plastic, polycarbonate resin thermoplastic, polymethyl methacrylate, and other suitable plastic materials.

10. The fixture as defined in claim 1 wherein the mesh structure comprises a pattern of desired shapes and channels directly formed in a top surface of the bottom support plate.

11. The fixture as defined in claim 1 wherein the mesh structure comprises woven material with spacings selected to provide a release force required to separate a particular wafer from the surface stiction film.

12. The fixture as defined in claim 1 wherein the polymer material for the surface stiction film is selected from the group consisting of: acrylic, plastic, silicone resins, cellulose, acetate sheets, polyethylene and other suitable polymer materials.

13. The fixture as defined in claim 1 wherein the wafer release mechanism comprises a Venturi vacuum generator formed within the bottom support plate.

14. The fixture as defined in claim 1 wherein the fixture further comprises a component for storing a unique ID of a supported wafer.

15. The fixture as defined in claim 14 wherein the component is further configured to store process fabrication data associated with the supported wafer.

16. The fixture as defined in claim 1 wherein the fixture further comprises an environmental history module for measuring and storing selected environmental factors experienced by the supported wafer during the post-fabrication handling process.

17. The fixture as defined in claim 16 wherein the environmental history module comprises a plurality of sensors including at least a pressure sensor, a temperature sensor and a humidity sensor.

18. The fixture as defined in claim 16 wherein the fixture further comprises a communication component for wirelessly transmitting data stored in the environmental history module to a remote location.

19. A method of handling a processed semiconductor wafer to prevent wafer bowing, the method including
disposing the processed semiconductor wafer on a wafer handling fixture, the wafer handling fixture comprising a bottom support plate including a wafer release mechanism, a mesh structure disposed to cover a major surface area of the bottom support plate and a surface film of a polymer material disposed on the mesh structure, the surface film creating a stiction force between the fixture and the processed semiconductor wafer placed on the surface film such that the wafer remains affixed to the fixture;
moving the wafer handling fixture with the disposed wafer to an operation station associated with a manufacturing process;
loading the wafer handling fixture onto the operation station such that an exposed surface of the processed semiconductor wafer contacts a support mechanism within the operation state;
applying a local vacuum force to hold the exposed surface of the processed semiconductor wafer against the support mechanism of the operation station; and
activating the release mechanism of the wafer handling fixture to overcome the stiction force between the wafer and the handling fixture, allowing an opposing wafer surface to be visible and allowing the wafer handling fixture to be removed from the vicinity of the operation station.

20. The method as defined in claim 19, further comprising the steps of
performing selected post-fabrication processes on the exposed opposing wafer surface;
re-positioning the wafer handling fixture over the visible opposing wafer surface, the contact causing the visible opposing wafer surface to re-adhere to the surface stiction film;
de-activating the local vacuum force; and
removing the wafer handling fixture and adhered wafer from the operation station.
